(19) United States
(12) Patent Application Publication
(10) Pub. No.: US 2017/0199437 A1
(43) Pub. Date: Jul. 13, 2017

(54) DISPLAY DEVICE INCLUDING ALIGNMENT LAYER DEFINING GROOVES AND MANUFACTURING METHOD THEREOF

(71) Applicant: Samsung Display Co., Ltd., Yongin-si (KR)

(72) Inventors: Seung-Yeon CHAE, Hwaseong-si (KR); Si Kwang KIM, Daegu (KR); Joo Young YOON, Suwon-si (KR); Gug Rae JO, Asan-si (KR)

(21) Appl. No.: 15/241,161

(22) Filed: Aug. 19, 2016

(30) Foreign Application Priority Data
Jan. 8, 2016 (KR) 10-2016-0002769

(51) Int. Cl. G02F 1/1337; H01L 27/12; G02F 1/1333; G02F 1/1362; G02F 1/1368; G02F 1/1343

(52) U.S. Cl. CPC G02F 1/133788; G02F 1/1368; G02F 1/134309; G02F 1/133345; G02F 1/133377; G02F 1/13439; G02F 1/136227; G02F 1/133711; H01L 27/1248; H01L 27/1262; G02F 2201/123; G02F 2201/121; G02F 2201/52; G02F 1/133514

(57) ABSTRACT

A display device includes: a substrate; a thin film transistor on the substrate; a pixel electrode connected to the thin film transistor; a common electrode overlapping the pixel electrode; an insulating layer between the pixel electrode and the common electrode; a roof layer spaced apart from the pixel electrode; a microcavity provided in plurality each defined between the roof layer and the pixel electrode spaced apart from each other; a first alignment layer between the microcavity and the pixel electrode and defining an upper surface thereof adjacent to the microcavity which defines a first groove of the first alignment layer; a second alignment layer between the microcavity and the roof layer and defining an upper surface thereof opposing the microcavity which defines a second groove of the second alignment layer; and an optical medium layer disposed in the plurality of microcavities.

This application claims priority to Korean Patent Application No. 10-2016-0002769 filed on Jan. 8, 2016, and all the benefits accruing therefrom under 35 U.S.C. §119, the content of which in its entirety is incorporated herein by reference.

### BACKGROUND

1. Field

The invention relates generally to a display device and a manufacturing method thereof.

2. Description of the Related Art

Liquid crystal displays are widely used as one type of flat panel display device. A liquid crystal display has two display panels in which field generating electrodes such as pixel electrodes and a common electrode are disposed, and a liquid crystal layer that is interposed between the two display panels. Voltages are applied to the field generating electrodes so as to generate an electric field in the liquid crystal layer, and the alignment of liquid crystal molecules of the liquid crystal layer is determined by the electric field. Accordingly, by alignment of the liquid crystal molecules of the liquid crystal layer, the polarization of incident light is controlled, thereby performing image display.

The two display panels of a liquid crystal display may be a thin film transistor array panel and an opposing display panel. In the thin film transistor array panel, a gate line transmitting a gate signal and a data line transmitting a data signal are formed to cross each other, and a thin film transistor connected to the gate line and the data line and a pixel electrode connected to the thin film transistor may be formed. The opposing display panel may include a light blocking member, a color filter, a common electrode, etc. The light blocking member, the color filter and the common electrode may be disposed in the thin film transistor array panel instead of the opposing display panel in some cases.

In a conventional flat panel display device such as the liquid crystal display having the two display panels, two base substrates are used. With the two base substrates, the constituent elements of the conventional liquid crystal display are respectively disposed on the two base substrates such that the conventional liquid crystal display is relatively heavy, the cost is relatively high, and the processing time thereof is relatively long.

### SUMMARY

One or more exemplary embodiment of the invention provides a display device including only one base substrate such that the display device and a manufacturing method thereof using only one substrate having advantages of reduced weight, thickness, cost and processing time.

When manufacturing the display device by using one single substrate therein, a process for injecting an alignment material into a microcavity is performed after forming the microcavity. The alignment material forms an alignment layer of the display device. For the alignment layer formed from the alignment material in the microcavity, performing a rubbing process of a contacting type on the alignment layer may be difficult because an upper surface of the alignment layer is not exposed outside the microcavity. Thus, a photo-alignment process using ultraviolet (“UV”) light to form the alignment layer has been developed. However, alignment capability of an optical medium disposed in the microcavity is deteriorated because of thick layers disposed on and under the microcavity when using the photo-alignment process. Thus, a light leakage defect undesirably occurs.

The described technology has been made in an effort to provide a display device and a manufacturing method thereof having advantages of improving optical medium alignment capability and reducing or effectively preventing light leakage defects.

A display device according to an exemplary embodiment includes: a substrate; a thin film transistor disposed on the substrate; a pixel electrode connected to the thin film transistor; a common electrode overlapping the pixel electrode; an insulating layer disposed between the pixel electrode and the common electrode; a roof layer spaced apart from the pixel electrode; a microcavity provided in plurality each defined between the roof layer and the pixel electrode spaced apart from each other; a first alignment layer disposed between the microcavity and the pixel electrode and defining an upper surface thereof adjacent to the microcavity, the upper surface of the first alignment layer defining a first groove of the first alignment layer; a second alignment layer disposed between the microcavity and the roof layer and defining an upper surface thereof opposing the microcavity, the upper surface of the second alignment layer defining a second groove of the second alignment layer; and an optical medium layer disposed in the plurality of microcavities.

The first groove may overlap at least one of the pixel electrode and the common electrode.

The first groove may define a length thereof larger than a width thereof, and an extension direction of the length of the first groove may define a first direction.

The substrate may further include a plurality of pixels, and the first groove is provided in plurality within each of the plurality of pixels, respectively.

The plurality of first grooves may define lengths thereof larger than widths thereof, and the lengths of the plurality of first grooves extend parallel to each other.

The plurality of first grooves may define lengths thereof larger than widths thereof, and the length of a respective first groove among the plurality of first grooves may define: a first length portion which lengthwise extends in a first direction, and a second length portion which lengthwise extends in a second direction different from the first direction.

The second groove may overlap at least one of the pixel electrode and the common electrode.

Each microcavity among the plurality of microcavities may be respectively defined by an upper surface thereof, a lower surface thereof, and a lateral surface thereof which connects the upper and lower surfaces to each other. The second groove may be disposed non-overlapping the lateral surface of the each microcavity.

The first alignment layer and the second alignment layer may include an ultraviolet-(“UV”) curable polymer.

A manufacturing method of a display device according to an exemplary embodiment includes: forming a first electrode on a substrate; forming a second electrode on the substrate; forming an insulating layer between the first electrode and the second electrode; forming a first alignment layer on the insulating layer and the second electrode; forming a sacrificial layer on the first alignment layer; forming a roof layer on the sacrificial layer; forming a microcavity between the second electrode and the roof layer by removing the sacrificial layer; and forming an optical medium layer by injecting an optical medium material into the microcavity. The forming of the first alignment layer includes defining an upper surface thereof adjacent to the microcavity and forming a first groove of the first alignment layer in the upper surface thereof.

In the forming of the first groove of the first alignment layer, a first mold is disposed on the upper surface of the first alignment layer, and pressed into the upper surface to define the first groove.

The first groove may overlap at least one of the first electrode and the second electrode.

The first groove may define a length thereof larger than a width thereof, and an extension direction of the length of the first groove may define a first direction.

The method may further include forming a plurality of pixels on the substrate, and the first groove may be provided in plurality within each of the plurality of pixels, respectively.

The plurality of first grooves may define lengths thereof larger than widths thereof, and the lengths of the plurality of first groove may extend parallel to each other.

The plurality of first grooves may define lengths thereof larger than widths thereof, and the length of a respective first groove among the plurality of first grooves may define: a first length portion which lengthwise extends in a first direction, and a second length portion which lengthwise extends in a second direction different from the first direction.

The manufacturing method may further include forming a second alignment layer on the sacrificial layer on the first alignment layer. The forming the second alignment layer may include defining an upper surface thereof opposing the microcavity and forming a second groove of the second alignment layer in the upper surface thereof.

In the forming of the second groove of the second alignment layer, a second mold is disposed on the upper surface of the second alignment layer, and pressed into the upper surface of the second alignment layer to define the second groove, and the second groove may overlap at least one of the first electrode and the second electrode.

Each microcavity among the plurality of microcavities may be respectively defined by an upper surface thereof, a lower surface thereof, and a lateral surface thereof which connects the upper and lower surfaces to each other. The second groove may be formed non-overlapping the lateral surface of the each microcavity.

The first alignment layer and the second alignment layer may include an ultraviolet-curable polymer.

The display device according to one or more exemplary embodiment has the following effects.

According to the exemplary embodiments, the display device is manufactured by using only one substrate, thereby decreasing the overall weight, thickness, cost and processing time of the display device.

Further, the display device improves liquid crystal alignment capability by forming an alignment layer from an ultraviolet (“UV”) curable polymer and forming a groove in a surface of the alignment layer such as by using a mold.

### BRIEF DESCRIPTION OF THE DRAWINGS

The above and other advantages and features of this disclosure will become more apparent by describing in further detail exemplary embodiments thereof with reference to the accompanying drawings, in which:

FIG. 1 is a top plan view of an exemplary embodiment of a display device according to the invention.

FIG. 2 is a cross-sectional view of an exemplary embodiment of the display device taken along line II-II of FIG. 1.

FIG. 3 is a cross-sectional view of an exemplary embodiment of a display device taken along line III-III of FIG. 1.

FIGS. 4 to 17 are cross-sectional views of exemplary embodiments of processes of a manufacturing method of a display device according to the invention.

FIG. 18 to FIG. 20 are top plan views of exemplary embodiments of various shapes of a first groove and a second groove of a display device according to the invention.

### DETAILED DESCRIPTION

The invention will be described more fully hereinafter with reference to the accompanying drawings, in which exemplary embodiments of the invention are shown. As those skilled in the art would realize, the described embodiments may be modified in various different ways, all without departing from the spirit or scope of the invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

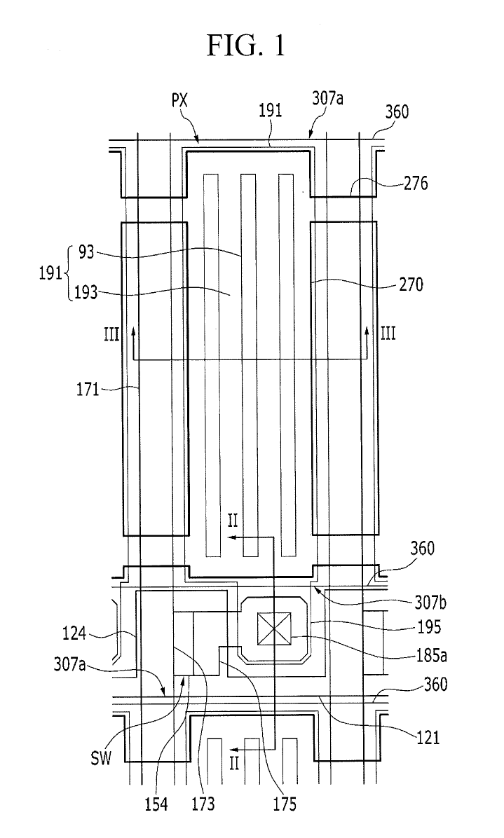

First, an exemplary embodiment of a display device according to the invention will be described with reference to FIG. 1 to FIG. 3.

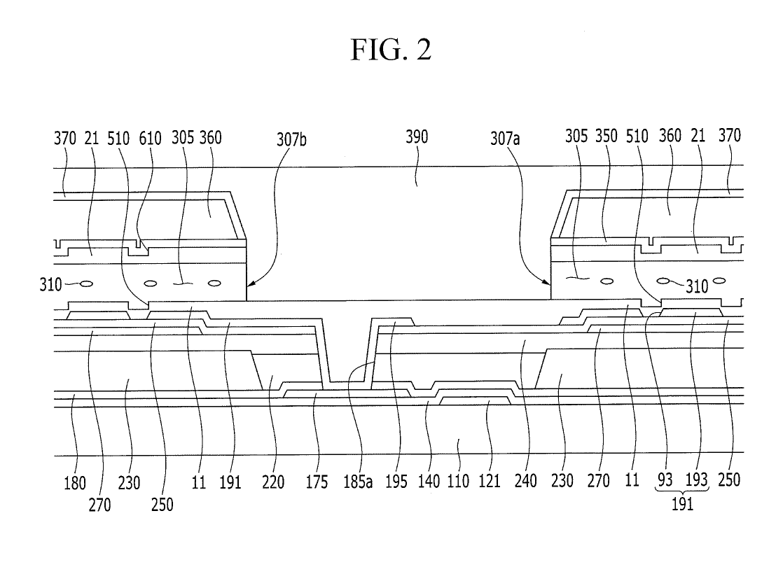

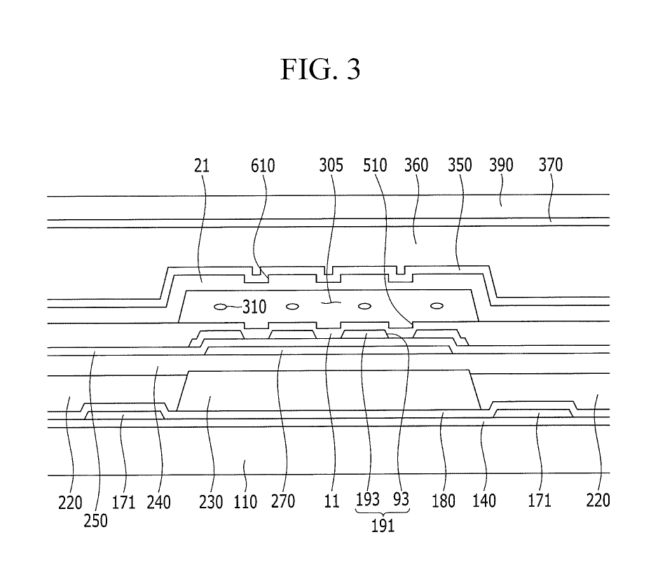

FIG. 1 is a top plan view of an exemplary embodiment of a display device according to the invention, FIG. 2 is a cross-sectional view of an exemplary embodiment of the display device of FIG. 1 taken along line II-II, and FIG. 3 is a cross-sectional view of an exemplary embodiment of the display device of FIG. 1 taken along line III-III.

Referring to FIG. 1 to FIG. 3, a gate line 121 and a gate electrode 124 which protrudes from a main portion of the gate line 121 are disposed on an insulation substrate 110 including or made of transparent glass or plastic. The gate line 121 may be considered as including and/or defining the gate electrode 124. The insulation substrate 110 defines the base substrate of the single-substrate display device. The insulation substrate 110 may be the only base substrate among layers of the display device.

In the top plan view, a length of the gate line 121 may mainly extend in a horizontal direction. The gate line 121 transmits a gate signal therethrough. The gate electrode 124 protrudes upward from the main portion of the gate line 121. However, the exemplary embodiment is not limited thereto, and a protruding shape of the gate electrode 124 may be variously modified. Alternatively, the gate electrode 124 may not protrude from the main portion of the gate line 121, and may be disposed on the same line as the main portion of the gate line 121.

A gate insulating layer 140 is disposed on the gate line 121 and the gate electrode 124. The gate insulating layer 140 may include or be made of an inorganic insulating material such as a silicon nitride (SiNx) and a silicon oxide (SiOx). Also, the gate insulating layer 140 may include or be formed of a single layer or multiple layers.

A semiconductor 154 is disposed on the gate insulating layer 140. The semiconductor 154 may be positioned on and overlapping the gate electrode 124 in the top plan view. The semiconductor 154 may also be positioned under a data line 171 in a thickness direction of the display device, in some exemplary embodiments. The semiconductor 154 may include or be formed of amorphous silicon, polycrystalline silicon or a metal oxide.

An ohmic contact (not shown) may be further disposed on and overlapping the semiconductor 154. The ohmic contact may include or be made of a silicide or of n+ hydrogenated amorphous silicon doped with an n-type impurity at a relatively high concentration.

The data line 171 and a drain electrode 175 which is separated from the data line 171 are disposed on the semiconductor 154 and the gate insulating layer 140. The data line 171 includes or defines a source electrode 173, and the source electrode 173 and the drain electrode 175 are positioned spaced apart from each other to face each other.

The data line 171 transmits a data signal therethrough. In the top plan view, a length of the data line mainly extends in a vertical direction, thereby crossing the gate line 121. For purposes of description, with reference to the top plan view of FIG. 1, a length direction of the gate line 121 may be defined as a horizontal direction and a length direction of the data line 171 may be defined as a vertical direction which crosses the horizontal direction. The thickness direction of the display device may be defined perpendicular to a plane defined by the horizontal and vertical directions described above. It is illustrated that the data line 171 linearly extends in a vertical direction. However, the exemplary embodiment is not limited thereto, and the data line 171 may have a shape that is periodically curved. In an exemplary embodiment, for example, the data line 171 may have shape that is curved at least once per pixel PX of the display device. The display device may include the pixel PX in plural. The pixel PX may be disposed or defined on the insulation substrate 110.

As shown in FIG. 1, the source electrode 173 does not protrude from a main portion of the data line 171, and may be disposed on the same line as the main portion of the data line 171. The drain electrode 175 may include a rod-shaped first end portion of which a length thereof extends substantially parallel to the source electrode 173, and an extension second end portion which is opposite to the rod-shaped first end portion.

The gate electrode 124, the source electrode 173 and the drain electrode 175 form one thin film transistor (“TFT”) together with the semiconductor 154. The thin film transistor may function as a switching element SW for transmitting the data voltage of the data line 171. A channel of the switching element SW is defined or formed in the semiconductor 154 which is exposed between the source electrode 173 and the drain electrode 175.

A passivation layer 180 is disposed on the data line 171, the source electrode 173, the drain electrode 175 and the exposed portion of the semiconductor 154. The passivation layer 180 may include or be made of an organic insulating material or inorganic insulating material, and may include or be formed of a single layer or multiple layers.

A color filter 230 may be provided in plural to be disposed in each pixel PX of the display device, on the passivation layer 180.

Each color filter 230 may display one primary color from among colors of red, green and blue. The color filter 230 is not limited to the three primary colors of red, green and blue, and may also display other colors such as cyan, magenta, yellow and white-based colors.

A light blocking member 220 is disposed at a region between adjacent color filters 230. The light blocking member 220 is disposed on or at a boundary of the pixel PX, and overlaps the gate line 121, data line 171 and thin film transistor to prevent light leakage thereat. However, the exemplary embodiment is not limited thereto, and the light blocking member 220 may overlap the gate line 121 and the thin film transistor, and may not overlap the data line 171. Where the light blocking member 220 does not overlap the data line 171, adjacent color filters 230 overlap each other on or at the data line 171 to prevent light leakage. The color filter 230 and the light blocking member 220 may overlap each other in a partial region thereof.

A first insulating layer 240 may be further disposed on the color filters 230 and the light blocking member 220. The first insulating layer 240 may include or be formed of an organic insulating material, and may serve to planarize the upper surface of each color filter 230 and the light blocking member 220. The first insulating layer 240 may include or be made of a dual layer including a layer made of an organic insulating material and a layer made of an inorganic insulating material. Also, the first insulating layer 240 may be omitted in some exemplary embodiments.

A common electrode 270 is disposed on the first insulating layer 240. The common electrode 270 may be provided in plural. Common electrodes 270 respectively disposed in the plurality of pixels PX are connected to each other through a connection bridge 276 and the like to transfer substantially the same voltage to each of the common electrodes 270. The common electrode 270 disposed in each pixel PX may have a planar shape. The common electrode 270 may include or be made of a transparent metal oxide such as indium-tin oxide (“ITO”) and indium-zinc oxide (“IZO”).

The common electrode 270 may be applied with a common voltage. The common voltage may be a predetermined voltage. Since the common voltage is applied through the common electrodes 270 and the connection bridge 276 therebetween, the collection of the common electrodes 270 and the connection bridge 276 may define a common voltage applying member.

A second insulating layer 250 is disposed on the common electrode 270. The second insulating layer 250 may include or be made of an inorganic insulating material such as a silicon nitride (SiNx) and a silicon oxide (SiOx).

The passivation layer 180, the first insulating layer 240 and the second insulating layer 250 define a contact hole 185a exposing at least a portion of the drain electrode 175. Particularly, the contact hole 185a exposes the extension second end portion of the drain electrode 175.

A pixel electrode 191 is disposed on the second insulating layer 250. The pixel electrode 191 may include or define a plurality of branch electrodes 193 and a slit 93 disposed between adjacent branch electrodes 193. In a top plan view, a length of the plurality of branch electrodes 193 and the slit 93 extend according to one direction. In an exemplary embodiment, for example, the plurality of branch electrodes 193 and the slit 93 extends linearly to be parallel to a linear length of the data line 171. However, the exemplary embodiment is not limited thereto. In another exemplary embodiment, for example, the data line 171, the plurality of branch electrodes 193 and the slit 93 may have a shape that is curved at least once per pixel PX.

Within a pixel PX, a plurality of branch electrodes 193 of the pixel electrode 191 overlaps the common electrode 270. In the thickness direction (e.g., cross-sectional view) of the display device, the pixel electrode 191 and the common electrode 270 are separated from each other by the second insulating layer 250. The second insulating layer 250 functions to insulate the pixel electrode 191 and the common electrode 270 from each other.

The pixel electrode 191 may include or define a protrusion 195 with which the pixel electrode 191 is connected with other layers of the display device. The protrusion 195 of the pixel electrode 191 is physically and electrically connected to the drain electrode 175 through and at the contact hole 185a, thereby receiving a voltage from the drain electrode 175. The pixel electrode 191 may include or be made of a transparent metal oxide such as indium-tin oxide (“ITO”) and indium-zinc oxide (“IZO”).

The pixel electrode 191 is applied with a data voltage. The data voltage is transmitted to the pixel electrode 191 through the data line 171 when the switching element SW is turned on.

The above-described arrangement of the pixel PX, the shape of the thin film transistor, and the locations and the shapes of the pixel electrode 191 and the common electrode 270 may vary. In addition, the deposition positions of the pixel electrode 191 and the common electrode 270 may be exchanged in the thickness direction of the display device. That is, the second insulating layer 250 is illustrated disposed on (e.g., above) the common electrode 270 and the pixel electrode 191 is illustrated disposed on (e.g., above) the second insulating layer 250, the second insulating layer 250 may be disposed on the pixel electrode 191 and the common electrode 270 may be disposed on the second insulating layer 250 in exemplary embodiments. In addition, the pixel electrode 191 may be made with or have a planar shape and the common electrode 270 may include or define the plurality of branch electrodes and the slit between adjacent branch electrodes.

A first alignment layer 11 is disposed on the pixel electrode 191 and second insulating layer 250. The first alignment layer 11 may include or be made of an ultraviolet (“UV”) curing polymer. The ultraviolet (“UV”) curing polymer is a material that is cured when ultraviolet (“UV” light is irradiated thereto. In an exemplary embodiment, for example, the ultraviolet (“UV”) curing polymer includes Norland Optical Adhesive 65 (“NOA 65”).

A first groove 510 is defined at or by an upper surface of the first alignment layer 11. The first groove 510 may overlap at least one of the pixel electrode 191 and common electrode 270. In the illustrated exemplary embodiment, the first groove 510 overlaps the slit 93 of the pixel electrode 191, and the common electrode 270. However, the exemplary embodiment is not limited thereto, and the first groove 510 may overlap the branch electrode 193 of the pixel electrode 191 instead of the slit 93 of the pixel electrode 191. In another exemplary embodiment, the first groove 510 may overlap the branch electrode 193 and the slit 93 of the pixel electrode 191 and the common electrode 270.

A plurality of first grooves 510 may be disposed in one pixel PX. The plurality of first grooves 510 may be arranged at regular intervals in a width direction thereof perpendicular to a length thereof. The plurality of first grooves 510 may define lengths thereof which extend according to a predetermined direction, and the lengths of the plurality of first grooves 510 may extend to be parallel to each other. The extending direction of the length of the first groove 510 may be parallel to the extending direction of the lengths of each of the data line 171, the branch electrode 193 and the slit 93. Alternatively, the extending direction of the length of the first groove 510 may form a predetermined angle with the extending direction of the lengths of each of data line 171, the branch electrode 193 and the slit 93.

A width and a depth of the first groove 510 and an interval between the plurality of first grooves 510 may vary. Optical medium alignment capability such as liquid crystal alignment capability may be controllable by variation of the width and the depth of the first groove 510 and the interval between the plurality of first grooves 510. In an exemplary embodiment, for example, liquid crystal alignment capability may be improved by increasing the depth of the first grooves 510 and narrowing the interval between adjacent first grooves 510. A depth of the first groove 510 may be defined from the upper surface of the first alignment layer 11 from which the first groove 510 is recessed, to a bottom surface of the recess. The depth may be a maximum distance between such upper surface and bottom surface.

A roof layer 360 to be separated from the pixel electrode 191 by a predetermined distance in the thickness direction of the display device, is disposed on the pixel electrode 191. The roof layer 360 may include or be made of an organic material. In the top plan view, the roof layer 360 may define a length thereof larger than a width thereof. The length of roof layer 360 may extend in a horizontal direction in the top plan view.

A microcavity 305 is provided or defined in plural each disposed between the pixel electrode 191 and the roof layer 360 in the thickness direction of the display device. Each microcavity 305 is enclosed by the pixel electrode 191 and the roof layer 360. The roof layer 360 covers an upper surface of the microcavity 305 and extends from the upper surface to cover a portion of lateral surfaces of the microcavity 305. In an exemplary embodiment of manufacturing the display device, a material of the roof layer 360 may be hardened by a curing process to maintain the final shape of the microcavity 305 in the display device. The size (e.g., length, width and/or depth) of the microcavity 305 may vary depending on the size and the resolution of the display device.

Referring to FIG. 2, for example, the roof layer 360 covering an upper surface of adjacent microcavities 305 does not extend to cover a portion of each of lateral surfaces at respective first and second edges of the adjacent microcavities 305. The portions of the adjacent microcavities 305 that are not covered by the roof layer 360 are referred to as injection holes 307a and 307b of the microcavities 305. The injection holes 307a and 307b include a first injection hole 307a which exposes an inner area of one of the two adjacent microcavities 305 at the lateral surface at the first edge of the one microcavity 305 and a second injection hole 307b which exposes an inner area of the other of the two adjacent microcavities 305 at the lateral surface at the second edge of the microcavity 305. The first edge of one microcavity 305 faces the second edge of the adjacent microcavity 305. In an exemplary embodiment, for example, the first edge may be an upper edge of the lower microcavity 305 and the second edge may be a lower edge of the upper microcavity 305 in the top plan view. In an exemplary embodiment of manufacturing the display device, the inner areas of the adjacent microcavities 305 are respectively exposed by the injection holes 307a and 307b so that an optical medium such as a liquid crystal material may be injected into the microcavity 305 through the injection holes 307a and 307b.

The optical medium is disposed in in the microcavity 305 positioned between the pixel electrode 191 and the roof layer 360. For a liquid crystal display device, a liquid crystal layer including or made of liquid crystal molecules 310 is disposed in the microcavity 305 positioned between the pixel electrode 191 and the roof layer 360. The liquid crystal molecules 310 have positive dielectric anisotropy or negative dielectric anisotropy. The liquid crystal molecules 310 may be arranged such that a long axis direction thereof is aligned parallel to the insulation substrate 110 in the absence of the electric field. That is, horizontal alignment may be realized. While a liquid crystal layer including or made of liquid crystal molecules 310 for a liquid crystal display device is described as an example, the invention is not limited thereto. In exemplary embodiments, for other display devices and/or display panels using only one base substrate, other optical mediums which control incident light thereto to thereby perform image display may be used.

The pixel electrode 191 applied with the data voltage through the switching element SW generates the electric field along with the common electrode 270 applied with the common voltage. such that the direction of the liquid crystal molecules 310 of the liquid crystal layer disposed in the microcavities 305 is determined. Particularly, the branch electrodes 193 of the pixel electrode 191 generate a fringe field in the liquid crystal layer along with the common electrode 270, thereby determining the arrangement direction of the liquid crystal molecules 310. As such, luminance of light passing through the liquid crystal layer varies according to the determined alignment directions of the liquid crystal molecules 310, thereby displaying an image.

A second alignment layer 21 is disposed under the roof layer 360 in the thickness direction of the display device. The second alignment layer 21 may include or be made of an ultraviolet (“UV”) curing polymer. In an exemplary embodiment, for example, the second alignment layer 21 includes Norland Optical Adhesive 65 (“NOA 65”).

A second groove 610 is defined at or by an upper surface of the second alignment layer 21. The second groove 610 may overlap at least one of the pixel electrode 191 and common electrode 270.

A plurality of second grooves 610 may be disposed in one pixel PX. The plurality of second grooves 610 may be arranged at regular intervals in a width direction thereof perpendicular to a length direction thereof. The plurality of second grooves 610 may define lengths thereof which extend according to a predetermined direction, and the plurality of second grooves 610 may extend to be parallel to each other. The extending direction of the lengths of the second groove 610 may be parallel to the extending direction of the lengths of each of the data line 171, the branch electrode 193 and the slit 93. Alternatively, the extending direction of the length of the second groove 610 may form a predetermined angle with the extending direction of the lengths of each of the data line 171, the branch electrode 193, and the slit 93.

The length extending direction of the second groove 610 may be parallel to the length extending direction of the first groove 510. The second groove 610 may overlap the first groove 510. However, the exemplary embodiment is not limited thereto, and the length extending direction of the second groove 610 may not be parallel to the length extending direction of the first groove 510. In another exemplary embodiment, the length extending direction of the second groove 610 may be parallel to the length extending direction of the first groove 510, and the second groove 610 may not overlap the first groove 510.

A width and a depth of the second groove 610 and an interval between the plurality of second grooves 610 may vary. Optical medium alignment capability such as liquid crystal alignment capability may be controllable by variation of the width and the depth of the second groove 610 and the interval between adjacent second grooves 610. A depth of the second groove 610 may be defined from the upper surface of the second alignment layer 21 from which the second groove 610 is recessed, to a bottom surface of the recess. The depth may be a maximum distance between such upper surface and bottom surface. The liquid crystal molecules 310 of the liquid crystal layer may align according to a predetermined direction by the first groove 510 defined or formed by the first alignment layer 11 and the second groove 610 defined or formed by the second alignment layer 21, in an initial state of the liquid crystal molecules 310. In an exemplary embodiment, for example, the liquid crystal molecules 310 may align according to the length extending direction of the first groove 510 and the second groove 610.

In the illustrated exemplary embodiment, the first and second grooves 510 and 610 are formed at or defined by a portion of the first and second alignment layers 11 and 21 contacting an upper surface and a lower surface of the microcavity 305. The first and second grooves 510 and 610 are not disposed at lateral surfaces of the microcavity 305, such as a portion of the second alignment layer 21 contacting lateral surfaces of the microcavity 305, or areas between adjacent microcavities 305.

When a predetermined pattern such as a groove is formed at or defined by a portion of the second alignment layer 21 contacting lateral surfaces of the microcavity 305, an aligned direction of liquid crystal molecules 310 disposed at the lateral surfaces of the microcavity 305 becomes twisted. In the illustrated exemplary embodiment, because the second groove 610 is not formed on a portion of the second alignment layer 21 contacting lateral surfaces of the microcavity 305, liquid crystal molecules 310 at the lateral surfaces of the microcavity 305 may be aligned according to a predetermined direction and not undesirably twisted. Thus, light leakage at the edges of the microcavity 305 may be reduced or effectively prevented.

A third insulating layer 350 may be further disposed between the roof layer 360 and the second alignment layer 21. The third insulating layer 350 may include or be made of an inorganic insulating material such as a silicon nitride (SiNx) and a silicon oxide (SiOx). Also, the third insulating layer 350 may be omitted in exemplary embodiments.

A fourth insulating layer 370 may be further disposed on the roof layer 360. The fourth insulating layer 370 may include or be made of an inorganic insulating material such as a silicon nitride (SiNx) or a silicon oxide (SiOx). The fourth insulating layer 370 may be formed to cover the upper surface and/or the lateral surface of the roof layer 360. The fourth insulating layer 370 protects the roof layer 360 which includes or is made of an organic material, and the fourth insulating layer 37 may be omitted in exemplary embodiments.

An encapsulation layer 390 is disposed on the fourth insulating layer 370. The encapsulation layer 390 is extended from above the microcavities 305 to lateral surfaces of the microcavities 305 to cover the injection holes 307a and 307b exposing the inner portion of the microcavity 305 to the outside. That is, the encapsulation layer 390 may seal the microcavity 305 so that the liquid crystal molecules 310 disposed inside the microcavity 305 cannot leak out. Since the encapsulation layer 390 contacts the optical medium such as the liquid crystal molecules 310, the encapsulation layer 390 includes or is made of a material that does not react with the optical medium such as the liquid crystal molecules 310. In an exemplary embodiment, for example, the encapsulation layer 390 may include or be made of parylene and the like.

It is illustrated that the encapsulation layer 390 is disposed on the roof layer 360 and covers the injection holes 307a and 307b. However, the exemplary embodiment is not limited thereto. The encapsulation layer 390 may not be disposed on the roof layer 360 and may only be disposed to cover the injection holes 307a and 307b at the first and second edges of the microcavities 305.

The encapsulation layer 390 may include multiple layers such as being a double layer structure or a triple layer structure. The double layer structure consists of two layers that are made of different materials. The triple layer structure consists of three layers, and materials of adjacent layers are different from each other. In an exemplary embodiment, for example, the encapsulation layer 390 may include a layer that includes or is made of an organic insulating material and a layer that includes or is made of an inorganic insulating material.

Although not shown, a polarizer may be further disposed on the upper surface of the above-described display device and the lower surface which opposes the upper surface of the display device. The polarizer may include a first polarizer and a second polarizer. The first polarizer may be attached on the lower surface of the insulation substrate 110, and the second polarizer may be attached on the encapsulation layer 390.

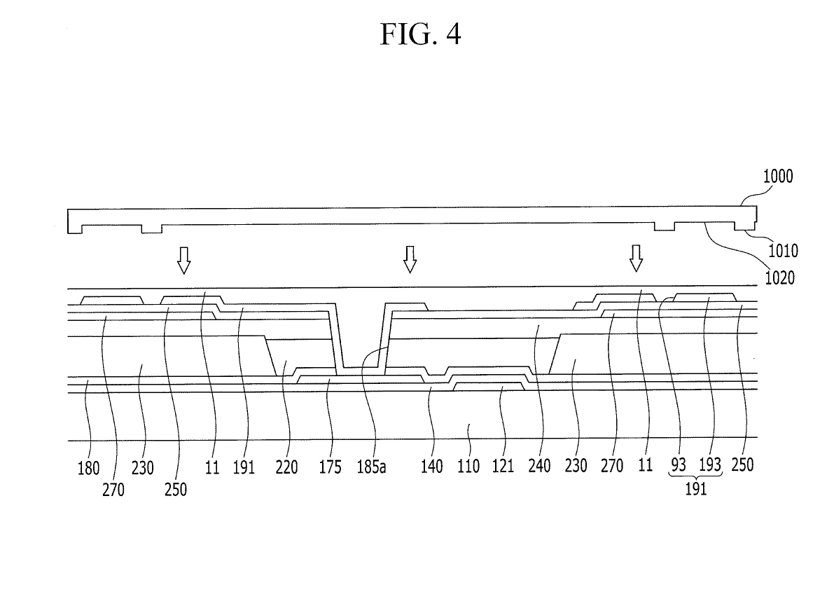

Next, with reference to FIG. 4 to FIG. 17, an exemplary embodiment of a manufacturing method of a display device according to the invention will be described as follows. In addition, the description will be made with reference to FIG. 1 to FIG. 3.

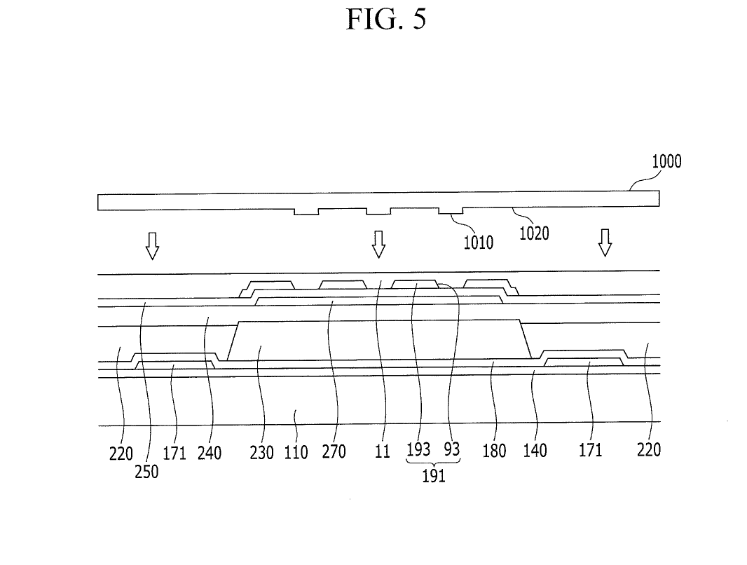

FIG. 4 to FIG. 17 are cross-sectional views of exemplary embodiments of processes of a manufacturing method of a display device according to the invention. FIGS. 4, 6, 8, 12, 14 and 16 may be views along line II-II of FIG. 1, and FIGS. 5, 7, 9, 11, 13, 15 and 17 may be views along line III-III of FIG. 1.

As shown in FIGS. 4 and 5, a gate line 121 defining a length thereof extending in a horizontal direction (refer to FIG. 1) and a gate electrode 124 which protrudes from a main portion of the gate line 121 are formed on a substrate 110. The substrate 110 includes or is made of glass or plastic. The length of the gate line 121 may substantially extend in a horizontal direction in a top plan view of the substrate 110. The gate line 121 and the gate electrode 124 are formed from a same material layer and disposed in a same layer among layers formed on the substrate 110.

Using an inorganic insulating material such as a silicon nitride (SiNx) or a silicon oxide (SiOx), a gate insulating layer 140 is formed on the gate line 121 and the gate electrode 124. The gate insulating layer 140 may include or be defined by a single layer or multiple layers.

A semiconductor material such as amorphous silicon, polycrystalline silicon, or a metal oxide is deposited on the gate insulating layer 140, and the semiconductor material is patterned to form a semiconductor 154 (refer to FIG. 1). The semiconductor 154 may be positioned on the gate electrode 124.

After depositing a metal material, the metal material is patterned to form a data line 171, a source electrode 173 and a drain electrode 175. The data line 171, the source electrode 173 and the drain electrode 175 may include or be defined by a single layer or multiple layers. The data line 171, the source electrode 173 and the drain electrode 175 are formed from a same material layer and disposed in a same layer among layers formed on the substrate 110. The data line 171 transmits a data signal therethrough and defines a length thereof which mainly extends in a vertical direction, thereby crossing the gate line 121. A length of the source electrode 173 may be disposed on the same line as that of the data line 171, and the drain electrode 175 is separated from the source electrode 173 by a predetermined distance.

In the above description, the method in which the semiconductor 154 is formed and then the metal material is deposited and patterned to form the data line 171, the source electrode 173 and the drain electrode 175 is described, but the exemplary embodiment is not limited thereto. That is, after the semiconductor material and the metal material are sequentially deposited, they may be simultaneously patterned to form the semiconductor 154, the data line 171, the source electrode 173 and the drain electrode 175. With the simultaneous patterning of the semiconductor material and the metal material sequentially deposited, the semiconductor 154 may be further disposed under the data line 171. The gate electrode 124, the source electrode 173 and the drain electrode 175 form one thin film transistor (“TFT”) together with the semiconductor 154.

A passivation layer 180 is formed on the data line 171, the source electrode 173 the drain electrode 175, and an exposed portion of the semiconductor 154 between the source and drain electrodes 173 and 175. The passivation layer 180 may include or be made of an organic insulating material or an inorganic insulating material, and may include or be defined by a single layer or multiple layers.

A color filter 230 is formed on the passivation layer 180. The color filter 230 may be formed inside each pixel (refer to PX in FIG. 1), and may not be formed at an edge of the pixel. A plurality of color filters 230 allowing different wavelengths to be transmitted therethrough may be formed within the display device, and color filters 230 of the same color may be formed along a vertical direction in the top plan view of the substrate 110. When forming color filters 230 of three colors, a color filter 230 of a first color may be formed first, a mask may be shifted to form a color filter 230 of a second color, and the same mask may be again shifted to form a color filter 230 of a third color.

Subsequently, a light blocking material is used to form a light blocking member 220 on the passivation layer 180. The light blocking member 220 may be positioned at the edge of the pixel, and may overlap the gate line 121, the data line 171, and the thin film transistor to prevent light leakage thereat. However, the exemplary embodiment is not limited thereto, and the light blocking member 220 may overlap the gate line 121 and the thin film transistor, but not the data line 171.

A first insulating layer 240 is formed on the color filter 230 and the light blocking member 220. The first insulating layer 240 may include or be formed of an organic insulating material, and may serve to planarize top surfaces of the color filter 230 and the light blocking member 220. The first insulating layer 240 may be formed as a dual layer structure by sequentially depositing a layer including or made of an organic insulating material and a layer including or made of an inorganic insulating material.

A transparent metal oxide material such as an indium tin oxide (“ITO”) or an indium zinc oxide (“IZO”) is deposited on the first insulating layer 240 and then patterned to form a common electrode 270. The common electrode 270 may be provided in plural on the substrate 110. Common electrodes 270 respectively disposed in the plurality of pixels PX are connected to each other through a connection bridge 276 (refer to FIG. 1) and the like to transfer substantially the same voltage to the common electrodes 270. The common electrode 270 disposed in each pixel PX may have a planar shape.

Using an inorganic insulating material such as a silicon nitride (SiNx) or a silicon oxide (SiOx), a second insulating layer 250 is formed on the common electrode 270. The second insulating layer 250, the light blocking member 220 and the passivation layer 180 are patterned to form extended therethrough a contact hole 185a that exposes at least a portion of the drain electrode 175.

A transparent metal material such as an indium tin oxide (“ITO”) or an indium zinc oxide (“IZO”) is deposited on the second insulating layer 250 and then patterned to form the pixel electrode 191. The pixel electrode 191 is connected to the drain electrode 175 through at the contact hole 185a. The pixel electrode 191 may include or define a plurality of branch electrodes 193 and a slit 93 which is disposed between adjacent branch electrodes 193.

Using an ultraviolet (“UV”) curing polymer, a first alignment layer 11 is formed on the pixel electrode 191 and the second insulating layer 250. The ultraviolet (“UV”) curing polymer is a material that is cured when irradiating ultraviolet (“UV”) light thereto. In an exemplary embodiment, for example, the ultraviolet (“UV”) curing polymer includes Norland Optical Adhesive 65 (“NOA 65”). The formed first alignment layer 11 may have a planarized upper surface.

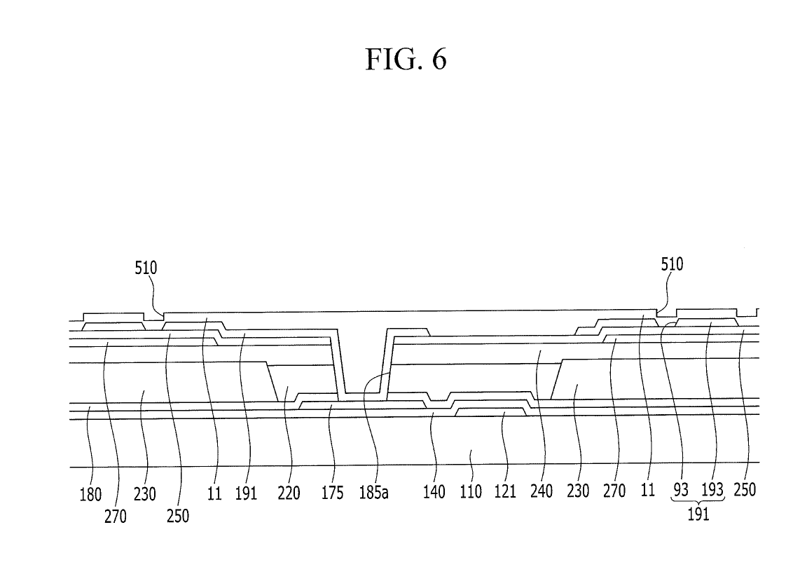

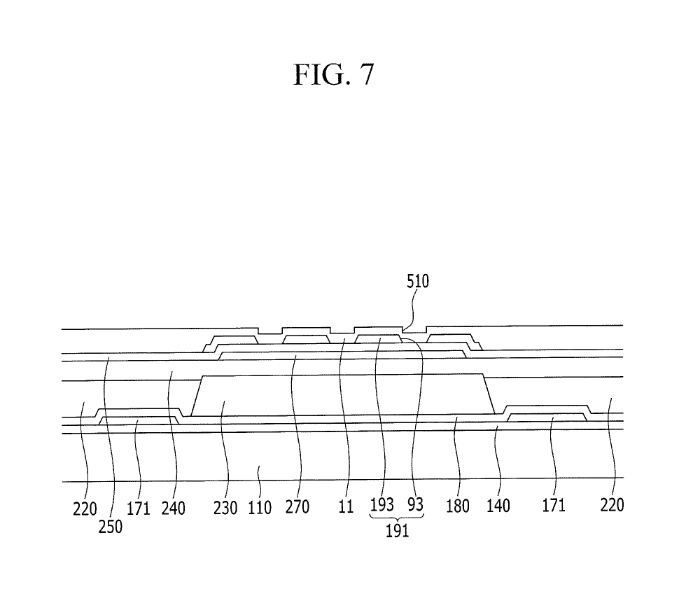

With the first alignment layer 11 formed on the pixel electrode 191 and the second insulating layer 250, a first mold 1000 is disposed over the first alignment layer 11. After the first mold 1000 is disposed on the first alignment layer 11, the first mold 1000 is moved downward (see arrows in FIGS. 4 and 5) and the formed first alignment layer 11 is compressed by the first mold 1000. As shown in FIGS. 6 and 7, by the first mold 1000 compressing the planarized upper surface of the first alignment layer 11, a first groove 510 is thereby formed in plural by compressed portions of the first alignment layer 11.

A lower surface of the first mold 1000 includes or defines a convex portion 1010 and a recess portion 1020. The first groove 510 is formed at a portion of the first alignment layer 11 which corresponds to the convex portion 1010 of the first mold 1000.

The first groove 510 may overlap at least one of the pixel electrode 191 and the common electrode 270. In the exemplary embodiment, the first groove 510 overlaps the slit 93 of the pixel electrode 191, and the common electrode 270. However, the exemplary embodiment is not limited thereto, and the first groove 510 may overlap the branch electrode 193 of the pixel electrode 191 instead of the slit 93 of the pixel electrode 191. In another exemplary embodiment, the first groove 510 may overlap the branch electrode 193 of the pixel electrode 191, the slit 93 of the pixel electrode 191 and the common electrode 270.

A plurality of first grooves 510 may be formed in one pixel PX (refer to FIG. 1). The plurality of first grooves 510 may be formed at regular intervals within the pixel PX. The plurality of first grooves 510 may define lengths thereof which extend according to a predetermined direction, and the lengths of the plurality of first grooves 510 may extend to be parallel to each other. The extending direction of the length of the first groove 510 may be parallel to the extending direction of lengths of each of the data line 171, the branch electrode 193 and the slit 93. In another exemplary embodiment, the extending direction of the length of the first groove 510 may form a predetermined angle with the extending direction of the lengths of each of the data line 171, the branch electrode 193 and the slit 93.

A width of the first groove 510 taken perpendicular to the length thereof, a depth of the first groove 510 in a thickness direction of the substrate 110, and an interval between the adjacent first grooves 510 in the width direction thereof may vary. Liquid crystal alignment capability may be controllable by variation of the width and the depth of the first groove 510 and the interval between the adjacent first grooves 510.

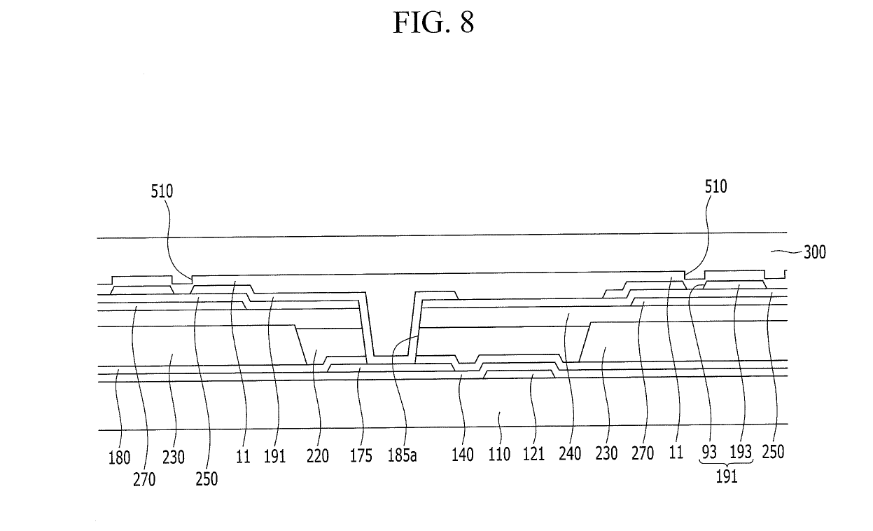

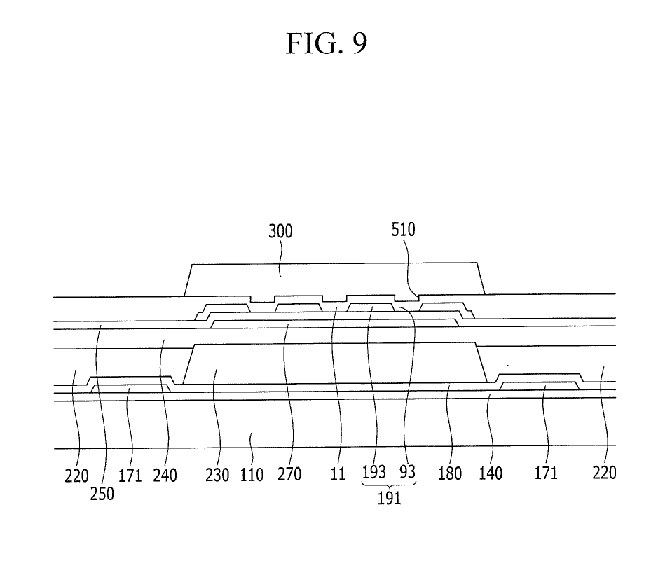

As shown in FIG. 8 and FIG. 9, a sacrificial layer 300 is formed on the first alignment layer 11 with the first grooves 510 defined therein. A sacrificial layer material may be deposited on the first alignment layer 11 with the first grooves 510 defined therein and then patterned to form the sacrificial layer 300. The sacrificial layer 300 may be formed to define a length thereof which extends in the vertical direction in the top plan view of the substrate 110. The sacrificial layer 300 may overlap the gate line 121, the thin film transistor and the pixel electrode 191, and the sacrificial layer 300 may not overlap the data line 171.

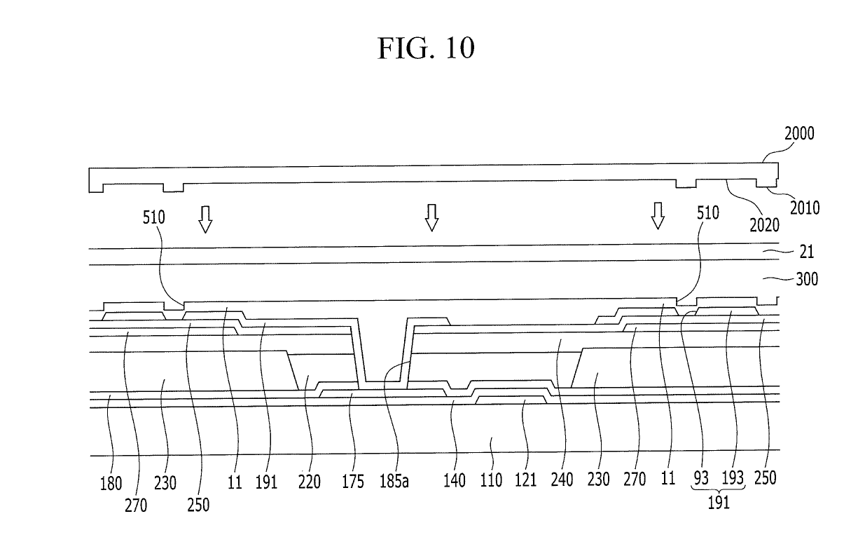

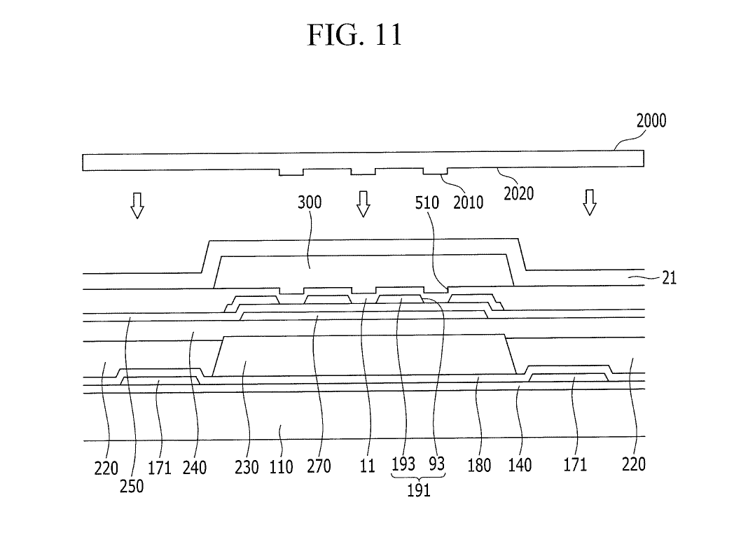

As shown in FIG. 10 and FIG. 11, using an ultraviolet (“UV”) curing polymer, a second alignment layer 21 is formed on the sacrificial layer 300 and the first alignment layer 11 with the first grooves 510 defined therein. The formed second alignment layer 21 may have a planarized upper surface.

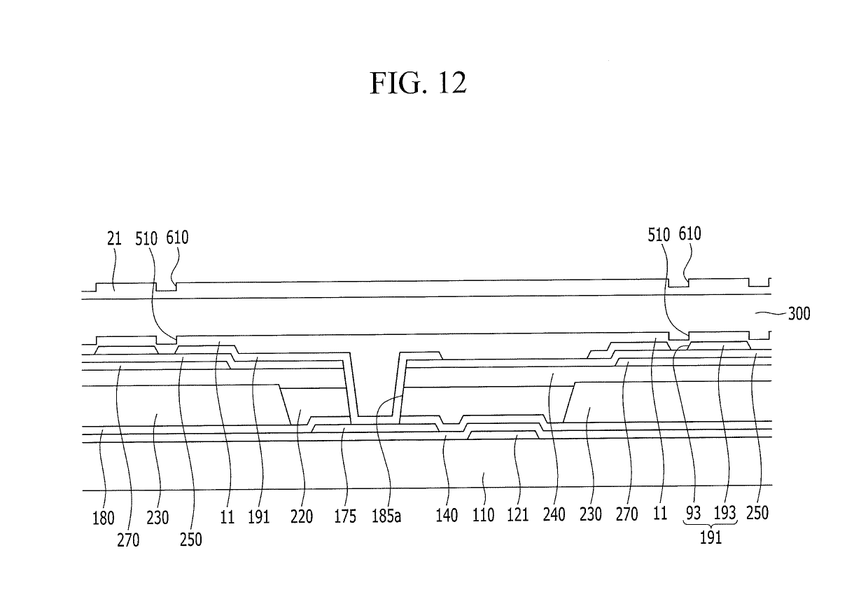

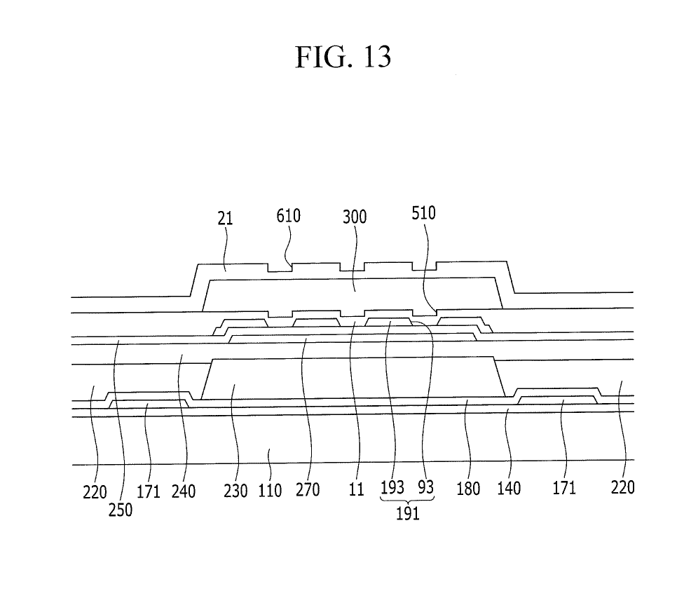

With the second alignment layer 21 formed on the sacrificial layer 300 and on the first alignment layer 11 with the first grooves 510 defined therein, a second mold 2000 is disposed over the second alignment layer 21. After the second mold 2000 is disposed on the second alignment layer 21, the second mold 2000 is moved downward (see arrows in FIGS. 10 and 11) and the formed second alignment layer 21 is compressed by the second mold 2000. As shown in FIGS. 12 and 13, by the second mold 2000 compressing the planarized upper surface of the second alignment layer 21, a second groove 610 is thereby formed in plural by compressed portions of the second alignment layer 21.

A lower surface of the second mold 2000 includes or defines a convex portion 2010 and a recess portion 2020. The second groove 610 is formed at a portion of the second alignment layer 21 which corresponds to the convex portion 2010 of the second mold 2000.

The second groove 610 may overlap at least one of the pixel electrode 191 and the common electrode 270.

A plurality of second grooves 610 may be formed in one pixel PX (refer to FIG. 1). The plurality of second grooves 610 may be formed in the same pixel PX (refer to FIG. 1) in which the first grooves 510 are formed. The plurality of second grooves 610 may be formed at regular intervals within the pixel PX. The plurality of second grooves 610 may define lengths thereof which extend according to a predetermined direction, and the lengths of the plurality of second grooves 610 may extend to be parallel to each other. The extending direction of the length of the second groove 610 may be parallel to the extending direction of the lengths of each of the data line 171, the branch electrode 193 and the slit 93. In another exemplary embodiment, the extending direction of the length of the second groove 610 may form a predetermined angle with the extending direction of the lengths of each of the data line 171, the branch electrode 193 and the slit 93.

The extending direction of the length of the second groove 610 may be parallel to the extending direction of the length of the first groove 510. The second groove 610 may overlap the first groove 510. However, the exemplary embodiment is not limited thereto, and the extending direction of the length of the second groove 610 may not be parallel to the extending direction of the length of the first groove 510. In another exemplary embodiment, the extending direction of the length of the second groove 610 may be parallel to the extending direction of the length of the first groove 510, and the second groove 610 may not overlap the first groove 510.

A width of the second groove 610 taken perpendicular to the length thereof, a depth of the second groove 610 in the thickness direction of the substrate 110, and an interval between adjacent second grooves 610 in the width direction thereof may vary. Liquid crystal alignment capability may be controllable by variation of the width and the depth of the second groove 610, and the interval between the adjacent second grooves 610.

The first groove 510 is formed at a portion of the first alignment layer 11 disposed at a lower surface of the sacrificial layer 300, and the second groove 610 is formed at a portion of the second alignment layer 21 disposed at an upper surface of the sacrificial layer 300. The first and second grooves 510 and 610 may be defined by the upper surfaces of the first and second alignment layers 11 and 21, respectively. Referring to FIG. 13, no groove is formed by portions of the first alignment layer 11 and the second alignment 21 at lateral surfaces of the sacrificial layer 300. The first and second alignment layers 11 and 21 respectively define the first and second grooves 510 and 610 spaced apart from lateral sides of the sacrificial layer 300.

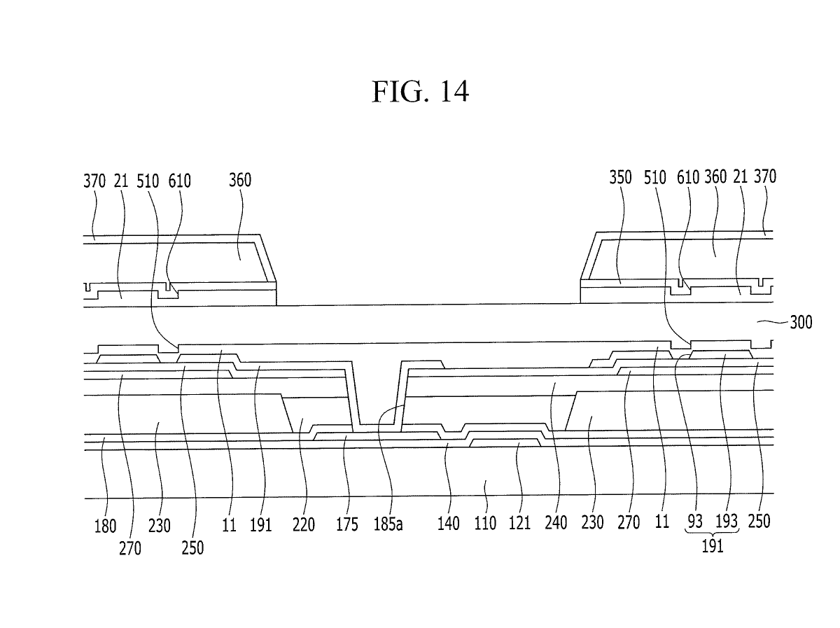

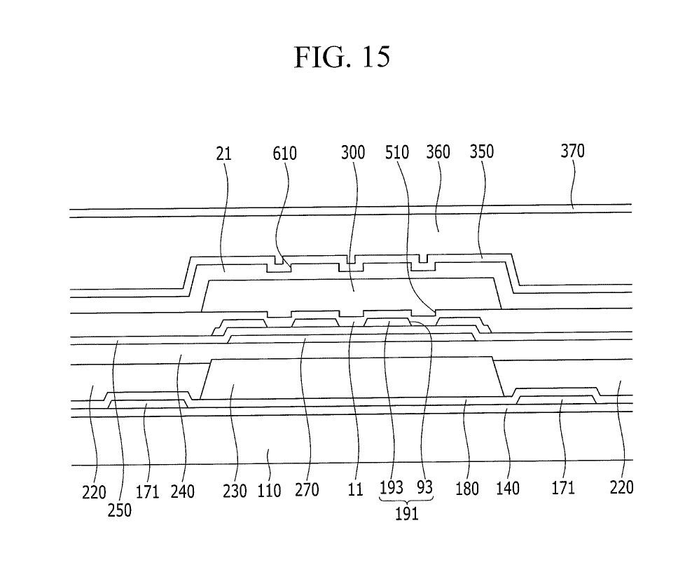

As shown in FIG. 14 and FIG. 15, using an inorganic insulating material such as a silicon nitride (SiNx) or a silicon oxide (SiOx), a third insulating layer 350 is formed on the second alignment layer 21 with the second grooves 610 defined therein.

An organic material is coated on the third insulating layer 350 and then patterned to form a roof layer 360. The patterning may be performed such that a portion of the organic material overlapping the gate line 121 and the thin film transistor is removed. Accordingly, the roof layer 360 may define a length thereof extended along a horizontal direction in the top plan view of the substrate 110. The removing of the organic material for forming the roof layer 360 which overlaps the gate line 121 and the thin film transistor exposes the underlying third insulating layer 350.

After the roof layer 360 is patterned as described above, light is irradiated to the roof layer 360 to perform a curing process for the forming material thereof. Since the roof layer 360 is hardened after performing the curing process, the roof layer 360 may maintain a shape thereof even if a predetermined space is created under the roof layer 360.

Portions of the exposed third insulating layer 350 and portions of the second alignment layer 21 thereunder overlapping the gate line 121 and the thin film transistor are removed by patterning the portions of the third insulating layer 350 and the second alignment layer 21 using the roof layer 360 as a mask. The removing of the portions of the third insulating layer 350 and the second alignment layer 21 exposes the underlying sacrificial layer 300 (refer to FIG. 14).

An inorganic insulating material such as a silicon nitride (SiNx) or a silicon oxide (SiOx) may be deposited on the patterned roof layer 360 and the exposed sacrificial layer 300, and then patterned to form a fourth insulating layer 370. The patterning may be performed such that a portion of the inorganic insulating material for forming the fourth insulating layer 370 overlapping the gate line 121 and the thin film transistor is removed and exposes the underlying sacrificial layer 300 previously exposed. As shown in FIGS. 14 and 15, the fourth insulating layer 370 may cover a top surface of the roof layer 360, and may further cover lateral surfaces of the roof layer 360 (refer to FIG. 14).

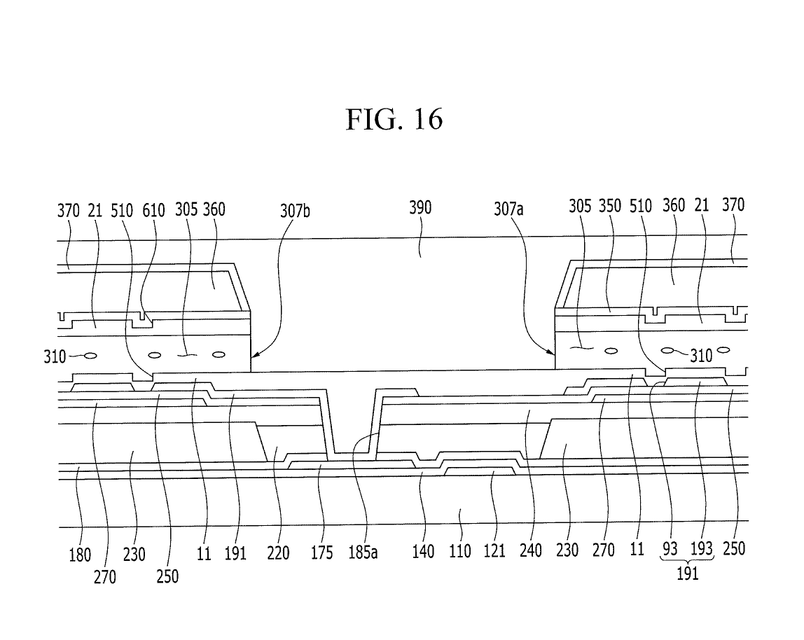

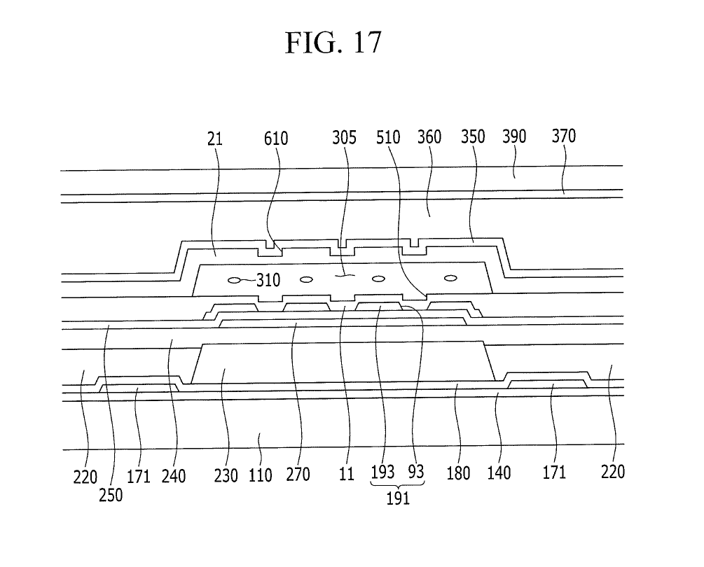

As the roof layer 360, the third insulating layer 350, the second alignment layer 21 and the fourth insulating layer 370 are patterned, a portion of the sacrificial layer 300 is exposed to the outside. When a developer or a stripper solution is supplied on the exposed sacrificial layer 300 to completely remove the sacrificial layer 300, or when an ashing process is used at the exposed sacrificial layer 300 to completely remove the sacrificial layer 300, a microcavity 305, as shown in FIGS. 16 and 17, is created at the position where the sacrificial layer 300 was previously positioned.

The pixel electrode 191 and the roof layer 360 are spaced apart from each other while interposing the microcavity 305 therebetween. As shown in FIGS. 16 and 17, the roof layer 360 covers a top surface of the microcavity 305, and extends to cover both lateral surfaces of the microcavity 305 (refer to FIG. 17).

The microcavity 305 is provided in plural on the substrate 110. An inner area of the microcavity 305 is exposed to the outside thereof through portions where the roof layer 360 is absent (refer to FIG. 16), and the portions of the microcavity 305 at which the inner area of the microcavity 305 is exposed may be defined as injection holes 307a and 307b. The injection holes 307a and 307b may be formed for one microcavity 305. In an exemplary embodiment, for example, a first injection hole 307a exposing the inner area of one microcavity 305 at a first lateral surface of a first edge of the microcavity 305 and a second injection hole 307b exposing the inner area of the same one microcavity 305 at a second lateral surface of a second edge of the microcavity 305 opposite to the first edge thereof, may be formed. The first edge and the second edge may oppose and face each other with respect to the inner area of the same one microcavity 305. Referring to the top plan view in FIG. 1, for example, the first edge of the one microcavity 305 may be an upper edge of the microcavity 305, while the second edge of the same one microcavity 305 may be a lower edge of the microcavity 305.

When an inkjet method or dispensing method is used to drip an optical medium material such as a liquid crystal (“LC”) material onto the substrate 110 having the microcavity 305 formed thereon, the LC material is injected through the injection holes 307a and 307b into the microcavity 305 by a capillary force. Accordingly, an optical medium layer such as a liquid crystal layer including liquid crystal molecules 310 is formed in the microcavity 305.

A material that does not react with the optical medium such as the liquid crystal molecules 310 is deposited on the fourth insulating layer 370 to form an encapsulation layer 390. Referring to FIGS. 16 and 17, the encapsulation layer 390 is formed such as extending from above the microcavity 305 to cover the injection holes 307a and 307b to seal the microcavity 305 (refer to FIG. 16), thereby preventing the liquid crystal molecules 310 formed in the microcavity 305 from leaking to the outside thereof. The forming of the encapsulation layer 390 on the substrate 110, with the above-described layers therebetween forms the display device.

Subsequently, although not illustrated, polarizers may be further attached to top and bottom surfaces of the display device described above. The polarizers may include a first polarizer and a second polarizer. The first polarizer may be attached on the lower surface of the substrate 110, and the second polarizer may be attached on the encapsulation layer 390.

Various planar shapes of the first groove 510 formed in or by the first alignment layer 11 and the second groove 610 formed in or by the second alignment layer 21 will be described with reference to FIG. 18 to FIG. 20.

FIG. 18 to FIG. 20 are top plan views of exemplary embodiments of various shapes of a first groove and a second groove of the display device according to the invention.

As shown in FIG. 18, a first groove 510 is formed in or by the first alignment layer 11, and a plurality of first grooves 510 are formed in each of respective pixels PX. The plurality of first grooves 510 defines lengths thereof which extend according to a first direction D1 to be parallel to each other.

A second groove 610 is formed in or by the second alignment layer 21, and a plurality of second grooves 610 are formed in each of respective pixels PX. The plurality of second grooves 610 defines lengths thereof which extend according to the first direction D1 to be parallel to each other.

As shown in FIG. 18, the first groove 510 and the second groove 610 overlap completely. An entirety of the first grooves 510 and the second grooves 610 is extended in one single direction, that is, the first direction D1. However, the exemplary embodiment is not limited thereto. The first groove 510 and the second groove 610 may be alternately formed.

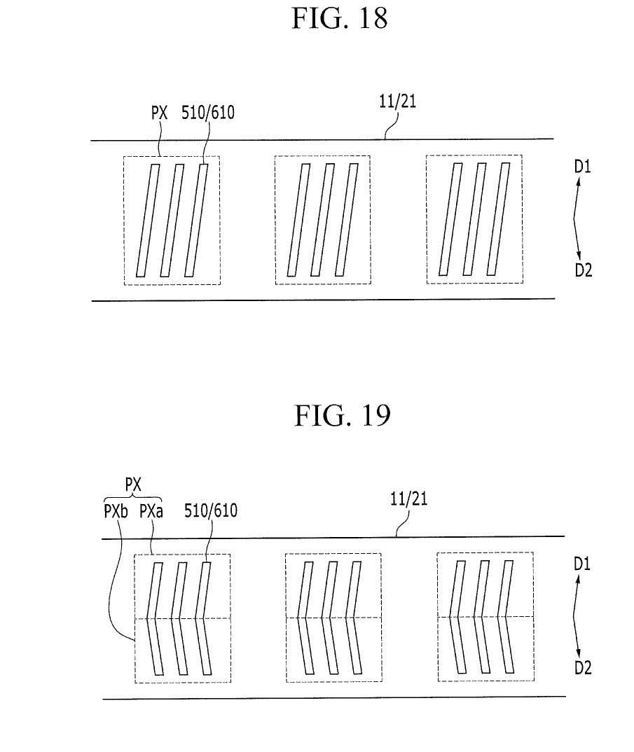

As shown in FIG. 19, a length of the first groove 510 extends according to a first direction D1 and a second direction D2. The pixel PX is divided into an upper region PXa and a lower region PXb. In the upper region PXa, a first length portion of the first groove 510 extends according to the first direction D1, and in the lower region PXb, a second length portion of the first groove 510 extends according to the second direction D2. An entirety of the first length portion is extended in the single first direction D1 and an entirety of the second length portion is extended in the single second direction D2. The first length portion of the first groove 510 extending according to the first direction D1 and the second length portion of the first groove 510 extending according to the second direction D2 may be connected to each other. The first and second length portions may form a single first groove 510.

Also, first and second length portions of the second groove 610 extend according to the first direction D1 and the second direction D2, respectively. The first groove 510 and the second groove 610 may overlap each other.

As the first groove 510 and the second groove 610 provided in plural each extend according to two directions in one pixel PX, a liquid crystal molecule disposed in the upper region PXa and a liquid crystal molecule disposed in the lower region PXb may align according to different directions from each other. Accordingly, the one pixel PX may be divided into two domains, and visibility may be improved. Further, as the first groove 510 and the second groove 610 extend according to more various directions than the two described above and that are different from each other, the one pixel PX may be divided into three or more domains.

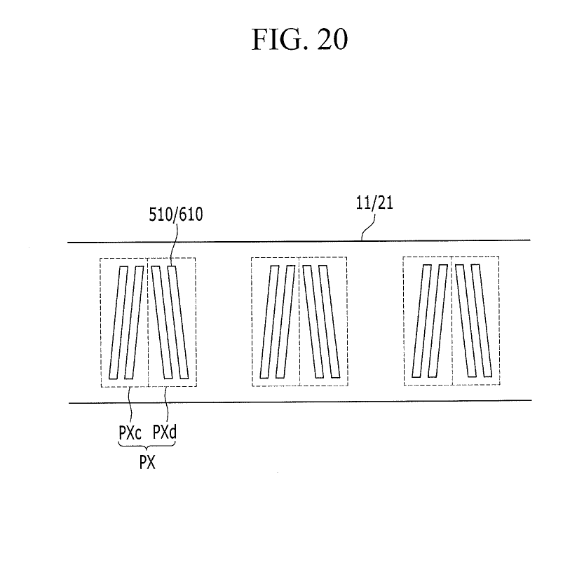

As shown in FIG. 20, a plurality of first grooves 510 is formed in respective pixels PX. A first group of the plurality of first grooves 510 defines lengths thereof which extend according to the first direction D1, and a second group of the plurality of first grooves 510 defines lengths thereof which extend according to the second direction D2.

One pixel PX is divided into a left region PXc and a right region PXd. In the left region PXc, lengths of the first groove 510 extend according to the first direction D1, while in the right region PXd, lengths of the first groove 510 extend according to the second direction D2.

A first group and a second group of the second groove 610 also defines lengths thereof which respectively extend according to the first direction D1 and the second direction D2. The first groove 510 and the second groove 610 overlap each other.

As the first groove 510 and the second groove 610 provided in plural each extend according to two directions in one pixel PX, a liquid crystal molecule disposed in the left region PXc and a liquid crystal molecule disposed in the right region PXd may align according to different directions from each other. Accordingly, the one pixel PX may be divided into two domains, and visibility may be improved. Further, as lengths of the first groove 510 and the second groove 610 extend according to more various directions than the two described above and that are different from each other, the one pixel PX may be divided into three or more domains.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A display device comprising:
a substrate;
a thin film transistor disposed on the substrate;
a pixel electrode connected to the thin film transistor;
a common electrode overlapping the pixel electrode;
an insulating layer disposed between the pixel electrode and the common electrode;
a roof layer spaced apart from the pixel electrode;
a microcavity provided in plurality each defined between the roof layer and the pixel electrode spaced apart from each other;
a first alignment layer disposed between the microcavity and the pixel electrode and defining an upper surface thereof adjacent to the microcavity, the upper surface of the first alignment layer defining a first groove of the first alignment layer;
a second alignment layer disposed between the microcavity and the roof layer and defining an upper surface thereof opposing the microcavity, the upper surface of the second alignment layer defining a second groove of the second alignment layer; and
an optical medium disposed in the plurality of microcavities.

2. The display device of claim 1, wherein
the first groove of the first alignment layer overlaps at least one of the pixel electrode and the common electrode.

3. The display device of claim 2, wherein
the first groove defines a length thereof larger than a width thereof, and
an extension direction of the length of the first groove defines a first direction.

4. The display device of claim 1, wherein
the substrate further comprises a plurality of pixels, and
the first groove is provided in plurality within each of the plurality of pixels, respectively.

5. The display device of claim 4, wherein
the plurality of first grooves defines lengths thereof larger than widths thereof, and
the lengths of the plurality of first grooves extend parallel to each other.

6. The display device of claim 4, wherein
the plurality of first grooves defines lengths thereof larger than widths thereof, and
the length of a respective first groove among the plurality of first grooves defines:
a first length portion which lengthwise extends in a first direction, and
a second length portion which lengthwise extends in a second direction different from the first direction.

7. The display device of claim 1, wherein
the second groove overlaps at least one of the pixel electrode and the common electrode.

8. The display device of claim 1, wherein
each microcavity among the plurality of microcavities is respectively defined by an upper surface thereof, a lower surface thereof, and a lateral surface thereof which connects the upper and lower surfaces to each other, and
the second groove of the second alignment layer is disposed non-overlapping with the lateral surface of the each microcavity.

9. The display device of claim 1, wherein
the first alignment layer and the second alignment layer comprise an ultraviolet-curable polymer.

10. A manufacturing method of a display device, comprising:
forming a first electrode on a substrate;
forming a second electrode on the substrate;
forming an insulating layer between the first electrode and the second electrode;
forming a first alignment layer on the insulating layer and the second electrode;
forming a sacrificial layer on the first alignment layer;
forming a roof layer on the sacrificial layer;
forming a microcavity between the second electrode and the roof layer by removing the sacrificial layer; and
forming an optical medium layer by injecting an optical medium material into the microcavity,
wherein
the forming of the first alignment layer comprises defining an upper surface thereof adjacent to the microcavity and forming a first groove of the first alignment layer in the upper surface thereof.

11. The manufacturing method of the display device of claim 10, wherein
in the forming of the first groove of the first alignment layer,
a first mold is disposed on the upper surface of the first alignment layer, and pressed into the upper surface to define the first groove.

12. The manufacturing method of the display device of claim 11, wherein
the first groove overlaps at least one of the first electrode and the second electrode.

13. The manufacturing method of the display device of claim 12, wherein
the first groove defines a length thereof larger than a width thereof, and
an extension direction of the length of the first groove defines a first direction.

14. The manufacturing method of the display device of claim 10, further comprising forming a plurality of pixels on the substrate,
wherein
the first groove is provided in plurality within each of the plurality of pixels, respectively.

15. The manufacturing method of the display device of claim 14, wherein
the plurality of first grooves defines lengths thereof larger than widths thereof, and
the lengths of the plurality of first groove extend parallel to each other.

16. The manufacturing method of the display device of claim 14, wherein
the plurality of first grooves defines lengths thereof larger than widths thereof, and
the length of a respective first groove among the plurality of first grooves defines:
a first length portion which lengthwise extends in a first direction, and
a second length portion which lengthwise extends in a second direction different from the first direction.

17. The manufacturing method of the display device of claim 10, further comprising:
forming a second alignment layer on the sacrificial layer on the first alignment layer,
wherein
the forming the second alignment layer comprises defining an upper surface thereof opposing the microcavity and forming a second groove of the second alignment layer in the upper surface thereof.

18. The manufacturing method of the display device of claim 17, wherein
in the forming of the second groove of the second alignment layer,
a second mold is disposed on the upper surface of the second alignment layer, and pressed into the upper surface of the second alignment layer to define the second groove, and
the second groove overlaps at least one of the first electrode and the second electrode.

19. The manufacturing method of the display device of claim 17, wherein
each microcavity among the plurality of microcavities is respectively defined by an upper surface thereof, a lower surface thereof, and a lateral surface thereof which connects the upper and lower surfaces to each other, and
the second groove of the second alignment layer is disposed non-overlapping with the lateral surface of the each microcavity.

20. The manufacturing method of the display device of claim 17, wherein
the first alignment layer and the second alignment layer comprise an ultraviolet-curable polymer.
